(19) United States
(12) Patent Application Publication
(10) Pub. No.: US 2022/0187699 A1
(43) Pub. Date: Jun. 16, 2022

(54) REFLECTIVE MASK BLANK FOR EUVL, REFLECTIVE MASK FOR EUVL, AND METHOD OF MANUFACTURING REFLECTIVE MASK FOR EUVL

(71) Applicant: AGC Inc., Tokyo (JP)

(72) Inventor: Hiroyoshi TANABE, Tokyo (JP)

(73) Assignee: AGC Inc., Tokyo (JP)

(21) Appl. No.: 17/541,795

(22) Filed: Dec. 3, 2021

(30) Foreign Application Priority Data
Dec. 11, 2020 (JP) 2020-205650
Nov. 11, 2021 (JP) 2021-184180

(51) Int. Cl. G03F 1/24; G03F 1/58; H01L 21/033

(52) U.S. Cl. CPC G03F 1/24; H01L 21/0332; H01L 21/0337; G03F 1/58

(57) ABSTRACT

A reflective mask blank for EUVL, includes a substrate; a multilayer reflective film reflecting EUV light; an absorber film absorbing EUV light; and an antireflective film. The multilayer reflective film, the absorber film, and the antireflective film are formed on or above the substrate in this order. The antireflective film includes an aluminum alloy containing aluminum (Al), and at least one metallic element selected from the group consisting of tantalum (Ta), chromium (Cr), titanium (Ti), niobium (Nb), molybdenum (Mo), tungsten (W), and ruthenium (Ru). The aluminum alloy further contains at least one element (X) selected from the group consisting of oxygen (O), nitrogen (N), and boron (B). An aluminum (Al) content of component of the aluminum alloy excluding the element (X) is greater than or equal to 3 at % and less than or equal to 95 at %.

### CROSS-REFERENCE TO RELATED APPLICATION

The present application claims priority under 35 U.S.C. § 119 to Japanese Patent Applications No. 2020-205650, filed Dec. 11, 2020 and No. 2021-184180, filed Nov. 11, 2021. The contents of which are incorporated herein by reference in their entirety.

### BACKGROUND OF THE INVENTION

### 1. Field of the Invention

The disclosures herein generally relate to a reflective mask for EUVL (Extreme Ultra Violet Lithography) used in a semiconductor production process, a reflective mask blank for EUVL that is an original plate of the reflective mask, and a method of manufacturing a reflective mask for EUVL.

### 2. Description of the Related Art

Conventionally, ultraviolet light with wavelengths of 365 to 193 nm has been used for light sources in photolithography devices used in semiconductor production. As the wavelength becomes shorter, resolution of the photolithography device becomes higher. In recent years, photolithography apparatuses using extreme ultraviolet (EUV) light with central wavelengths of about 13.5 nm for light sources have been in practical use.

EUV light is readily absorbed by various kinds of substances. Thus, a refractive optical system cannot be employed for the photolithography device. For this reason, in the EUV lithography, a catoptric system and a reflective mask are employed.

In the reflective mask, a multilayer reflective film that reflects EUV light is formed on a substrate, and an absorber film that absorbs EUV light is formed in a pattern on the multilayer reflective film.

For the substrate, low thermal expansion glass in which a small amount of titanium is added to synthetic quartz is often used in order to suppress pattern distortion caused by thermal expansion during photolithography. For the multilayer reflective film, a film in which a molybdenum film and a silicon film are alternately laminated for about 40 cycles is normally employed.

Conventionally, tantalum-based materials are often used for the absorber film. Tantalum-based materials have relatively high extinction coefficients, and thus function as binary masks with high light shielding properties. In recent years, ruthenium-based materials with relatively low extinction coefficients have also been investigated as the absorber films in order to improve resolution due to phase shift effects.

Because the absorber film is formed in a pattern on the multilayer reflective film, EUV light incident on the reflection mask from the catoptric system of the photolithography apparatus is reflected in the portion in which the absorber film is not present (aperture portion) and absorbed in the portion in which the absorber film is present (non-aperture portion). Thus, the aperture of the absorber film is transferred as a mask pattern to a surface of an exposure material (wafer coated with resist).

In the EUV lithography, EUV light typically enters the reflective mask from a direction at an angle of about 6 degrees with respect to the normal direction of the surface of the reflective mask and reflects in a direction at an angle of about 6 degrees with respect to the normal direction.

The absorber film is formed by sputtering. The film is typically deposited with a thickness of about 50 to 70 nm. The thickness of the absorber film may slightly deviate from the target film thickness or may vary within the mask surface. The deviation in the thickness of the absorber film may lead to a deviation in the reflectance and the phase shift amount of the absorber film, and consequently variation in resist line widths after the photolithography to the wafer.

Japanese Unexamined Patent Application Publication No. 2005-268255 discloses that a variation in a reflection coefficient of an absorber film (absorbing film) can be suppressed by a two or more-layer structure of the absorber film (absorbing film) and an uppermost layer formed of silicon or a material containing 90 at % or more of silicon. FIG. 4 in Japanese Unexamined Patent Application Publication No. 2005-268255 shows that a variation of an OD value in an entire absorber film is small even when a thickness of the uppermost layer is changed. The OD value represents an effective reflectance of the absorber film (absorbing film) when a reflectance of the multilayer film is assumed to be 100%. Since the reflectance of the actual multilayer film does not vary significantly around 65%, the OD value can be regarded to be an index representing the reflectance of the absorber film (absorbing film). That is, Japanese Unexamined Patent Application Publication No. 2005-268255 shows that the variation in the reflectance of the entire absorber film (absorbing film) is small even when the thickness of the uppermost layer is changed.

### SUMMARY OF INVENTION

### Problem to be Solved by the Invention

The refractive index n of Si for EUV light having a wavelength of 13.5 nm is 0.999, and the extinction coefficient k is 0.002. They are almost equal to the values in vacuum, respectively. Similarly, for a material containing 90 at % or more of Si, the refractive index is close to 1, and the extinction coefficient is nearly zero. Accordingly, Japanese Unexamined Patent Application Publication No. 2005-268255 merely shows that the variation in the reflectance of the uppermost layer is small when the thickness of the uppermost layer is changed, and is silent about whether the variation in the reflectance of the absorber film can be suppressed when the thickness of the entire absorber film is changed.

For solving the above-described problems of the background arts, an object of the present invention is to provide a reflective mask for EUVL that can suppress variations in the reflectance and the phase shift amount caused by variations in film thickness of an entire absorber film, a reflective mask blank for EUVL for the reflective mask, and a method of manufacturing the reflective mask for EUVL.

### Means for Solving Problems

As a result of an intensive study in order to achieve the above-described object, the inventor of the present invention has discovered that it is possible to suppress the variation in the reflectance and the phase shift amount caused by the variation in the thickness of the absorber film by providing a predetermined antireflective film on the absorber film.

The reason why the reflectance and the phase shift amount vary due to the variation in the thickness of the absorber film will be explained with reference to FIG. 2. A reflective mask blank for EUVL 100 shown in FIG. 2 is obtained by forming a multilayer reflective film 120 that reflects EUV light, and an absorber film 140 that absorbs EUV light, on a substrate 110, in this order.

In FIG. 2, incident light incident on the reflective mask blank for EUVL 100 at an incident angle of about 6 degrees generates reflected light A and reflected light B. The reflected light A is light that passes through the absorber film 140 and is reflected by the multilayer reflective film 120. When the thickness of the absorber film 140 is changed, an optical path length varies, and a phase of the reflected light A varies.

The reflected light B is light that is reflected at the surface of the absorber film 140. The phase of the reflected light B does not vary even when the thickness of the absorber film 140 is changed.

Thus, when the thickness of the absorber film 140 is changed, a phase difference between the reflected light A and the reflected light B also varies. Because an amplitude of the reflected light of the absorber film 140 is an amplitude of a superposition of the reflected light A and the reflected light B, when interference occurs, the reflectance and the phase shift amount vary due to the phase difference between the reflected light A and the reflected light B.

In the following, the above explanation will be presented using mathematical expressions. The amplitude r of the reflected light of the absorber film 140 can be expressed by the following equation.

[Math 1]

r=r_{A}+r_{B} (1)

where the amplitude of the reflected light A is r_{A} and the amplitude of the reflected light B is r_{B}. All values in Equation (1) are complex numbers. The reflectance is obtained by calculating using a square of the absolute value of the amplitude r, and the phase shift is calculated from a phase of the amplitude r.

A reflective mask blank for EUVL 200 shown in FIG. 3 is obtained by forming a multilayer reflective film 220 that reflects EUV light; an absorber film 240 that absorbs EUV light; and an antireflective film 250, on a substrate 210, in this order.

In FIG. 3, incident light incident on the reflective mask blank for EUVL 200 at an incident angle of about 6 degrees generates reflected light A, reflected light B, and reflected light C. A reflected light A is light that passes through the antireflective film 250 and the absorber film 240, and is reflected by the multilayer reflective film 220. The reflected light C is light that passes through the antireflective film 250 and is reflected at the surface of the absorber film 240. The reflected light B is light reflected at the surface of the antireflective film 250. In order to obtain the anti-reflection effect, the reflected light C on the surface of the absorber film 240 and the reflected light B on the surface of the antireflective film 250 may be set to cancel each other.

According to Fresnel's law of reflection, the amplitude r_{B} of the reflected light B can be expressed by Equation (2) as follows.

$$\begin{matrix}[ Math 2 ] & \\ {r}_{B} = \frac{{n}^{′} + {ik}^{′} - n - i k}{{n}^{′} + {ik}^{′} + n + i k} ∼ \frac{( {n}^{′} + {ik}^{′} - n - i k )}{2} & ( 2 )\end{matrix}$$

where the refractive index and the extinction coefficient of the absorber film 240 at the wavelength of EUV light are n and k, respectively, and the refractive index and the extinction coefficient of the antireflective film 250 are n′ and k′, respectively.

Here, since the refractive indices n and n′ at the wavelength of EUV light are close to 1 and the extinction coefficient k and k′ are close to 0, Equation (2) can be approximated to be (n′+ik′−n−ik)/2. In the same manner as above, the amplitude r_{C} of the reflected light C can be expressed by Equation (3) as follows.

$$\begin{matrix}[ Math 3 ] & \\ {r}_{c} = \frac{1 - {n}^{′} - {ik}^{′}}{1 + {n}^{′} + {ik}^{′}} ∼ \frac{( 1 - {n}^{′} - {ik}^{′} )}{2} . & ( 3 )\end{matrix}$$

An optical path length difference is present between the reflected light B and the reflected light C. The optical path length difference is 2n′d where d is a film thickness of the antireflective film 250. In order to cancel the reflected light B by the reflected light C completely, the following equations (4) and (5) are required to be satisfied.

$$\begin{matrix}[ Math 4 ] & \\ \frac{\sqrt{{( n - {n}^{′} )}^{2} + {( k - {k}^{′} )}^{2}}}{2} = \frac{\sqrt{{( 1 - {n}^{′} )}^{2} + {k}^{′2}}}{2} & ( 4 ) \\ [ Math 5 ] & \\ Arg ( {r}_{B} ) + \frac{4 π}{λ} {n}^{′} d - Arg ( {r}_{C} ) = ( 2 m + 1 ) π . & ( 5 )\end{matrix}$$

where λ in Equation (5) is a wavelength, and m is an integer greater than or equal to 0. Equation (5) is a formula for determining the film thickness d of the antireflective film 250 so that the phase of the reflected light C is an inverted phase of the phase of the reflected light B. The optimal value of the film thickness is determined in accordance with the material of the antireflective film 250.

Equation (4) is important in terms of the material of the antireflective film 250. In order to obtain the anti-reflection effect, it is necessary to select the antireflective film 250 having the refractive index n′ and the extinction coefficient k′ satisfying or approximately satisfying Equation (4) for the absorber film having the refractive index n and the extinction coefficient k. In order to obtain sufficient anti-reflection effect, Equation (6) is preferably satisfied.

$$\begin{matrix}[ Math 6 ] & \\ - 0.02 < \frac{( \sqrt{{( n - {n}^{′} )}^{2} + {( k - {k}^{′} )}^{2}} - \sqrt{{( 1 - {n}^{′} )}^{2} + {k}^{{′}^{2}}} )}{2} < 0.02 & ( 6 )\end{matrix}$$

By providing an antireflective film 250 made of the material that satisfies Equation (6) on the absorber film 240, it is possible to suppress variation in the reflectance and the phase shift amount caused by variation in the thickness of the entire absorber film. In the following, an area of complex refractive index that satisfies Equation (6), and does not satisfy Equation (7), which will be described below, will be referred to as a semi-optimal area.

Equation (4) is important in terms of the material of the antireflective film 250. In order to obtain the anti-reflection effect, it is necessary to select the antireflective film 250 having the refractive index n′ and the extinction coefficient k′ satisfying or approximately satisfying Equation (4) for the absorber film having the refractive index n and the extinction coefficient k. In order to obtain sufficient anti-reflection effect, Equation (7) is more preferably satisfied.

$$\begin{matrix}[ Math 7 ] & \\ - 0.01 < \frac{( \sqrt{{( n - {n}^{′} )}^{2} + {( k - {k}^{′} )}^{2}} - \sqrt{{( 1 - {n}^{′} )}^{2} + {k}^{{′}^{2}}} )}{2} < 0.01 & ( 7 )\end{matrix}$$

By providing an antireflective film 250 made of the material that satisfies Equation (7) on the absorber film 240, it is possible to suppress variation in the reflectance and the phase shift amount caused by variation in the thickness of the entire absorber film. In the following, an area of complex refractive index that satisfies Equation (7) will be referred to as an optimal area.

Based on the above-described findings, the inventors of the present application have found that the above-described problem can be solved by the following configurations.

[1] A reflective mask blank for EUVL, including a substrate; a multilayer reflective film reflecting EUV light; an absorber film absorbing EUV light; and an antireflective film, the multilayer reflective film, the absorber film; and the antireflective film being formed on or above the substrate in this order, the antireflective film including an aluminum alloy containing aluminum (Al), and at least one metallic element selected from the group consisting of tantalum (Ta), chromium (Cr), titanium (Ti), niobium (Nb), molybdenum (Mo), tungsten (W) and ruthenium (Ru), the aluminum alloy further containing at least one element (X) selected from the group consisting of oxygen (O), nitrogen (N) and boron (B), an aluminum (Al) content of component of the aluminum alloy excluding the element (X) being greater than or equal to 3 at % and less than or equal to 95 at %.

[2] A reflective mask blank for EUVL including a substrate; a multilayer reflective film reflecting EUV light; an absorber film absorbing EUV light; and an antireflective film, the multilayer reflective film, the absorber film, and the antireflective film being formed on or above the substrate in this order, a refractive index n and an extinction coefficient k of the absorber film for EUV light having a wavelength of 13.5 nm and a refractive index n′ and an extinction coefficient k′ of the antireflective film for EUV light having a wavelength of 13.5 nm satisfying Equation (6), which will be described later.

[3] The reflective mask blank for EUVL according to [2], the antireflective film including at least one metallic element selected from the group consisting of aluminum (Al), tantalum (Ta), chromium (Cr), titanium (Ti), niobium (Nb), molybdenum (Mo), tungsten (W), and ruthenium (Ru), and further including at least one element (Y) selected from the group consisting of oxygen (O), nitrogen (N), boron(B), hafnium (Hf), and hydrogen (H).

[4] The reflective mask blank for EUVL according to [3], the antireflective film including an aluminum alloy, containing aluminum (Al), at least one metallic element selected from the group consisting of tantalum (Ta), chromium (Cr), titanium (Ti), niobium (Nb), molybdenum (Mo), tungsten (W), and ruthenium (Ru), and the element (Y), and an aluminum (Al) content of component of the aluminum alloy excluding the element (Y) being greater than or equal to 3 at % and less than or equal to 95 at %.

[5] The reflective mask blank for EUVL according to [1], a film thickness of the antireflective film being greater than or equal to 2 nm and less than or equal to 5 nm or greater than or equal to 8 nm and less than or equal to 12 nm.

[6] The reflective mask blank for EUVL according to [1], the absorber film including at least one metallic element selected from the group consisting of ruthenium (Ru), chromium (Cr), tin (Sn), gold (Au), platinum (Pt), rhenium (Re), hafnium (Hf), tantalum (Ta), and titanium (Ti), and further including at least one element (Y) selected from the group consisting of oxygen (O), nitrogen (N), boron (B), hafnium (Hf), and hydrogen (H).

[7] The reflective mask blank for EUVL according to [1], the absorber film including at least one metallic element selected from the group consisting of tantalum (Ta), titanium (Ti), tin (Sb), and chromium (Cr), and further includes at least one element (Y) selected from the group consisting of oxygen (O), nitrogen (N), boron (B), hafnium (Hf) and hydrogen (H).

[8] The reflective mask blank for EUVL according to [1], the absorber film including an alloy including tantalum (Ta) and niobium (Nb), or a compound in which at least one element (Y) selected from the group consisting of oxygen (O), nitrogen (N), boron (B), hafnium (Hf), and hydrogen (H) is added to the alloy.

[9] The reflective mask blank for EUVL according to [1] further including a protective film for the multilayer reflective film between the multilayer reflective film and the absorber film.

[10] The reflective mask blank for EUVL according to [1] further including a hard mask film on the antireflective film, the hard mask film including one element selected from the group consisting of silicon (Si) and chromium (Cr); or a compound in which at least one element selected from the group consisting of oxygen (O), nitrogen (N), carbon (C), and hydrogen (H) is added to silicon (Si) or chromium (Cr).

[11] A reflective mask for EUVL, obtained by forming a pattern in the absorber film and in the antireflective film of the reflective mask blank for EUVL according to [1].

[12] A method of manufacturing a reflective mask for EUVL, the method including forming a pattern in the absorber film and in the antireflective film of the reflective mask blank for EUVL according to [1].

### Effects of the Invention

According to the present invention, a reflective mask for EUVL in which variations in the reflectance and the phase shift amount caused by variations in film thickness of the absorber film is suppressed, and a reflective mask blank for EUVL for the reflective mask for EUVL can be provided.

### BRIEF DESCRIPTION OF DRAWINGS

Other objects and further features of the present disclosure will be apparent from the following detailed description when read in conjunction with the accompanying drawings, in which:

FIG. 1 is a schematic cross-sectional diagram illustrating one embodiment of a reflective mask blank for EUVL of the present invention;

FIG. 2 is a diagram illustrating reflected light at an absorber film in the reflective mask blank for EUVL;

FIG. 3 is a diagram illustrating reflected light at an absorber film in a reflective mask blank for EUVL provided with an antireflective film;

FIG. 4 is a diagram illustrating complex refractive indices of Ta, Cr, Ti, Nb, Mo, W, Ru, Si and Al;

FIG. 5 is a diagram illustrating an optimal area of the complex refractive index of the antireflective film 15 when the absorber film 14 is a RuO₂ film;

FIG. 6 is a diagram illustrating the optimal area of the complex refractive index of the antireflective film 15 when the absorber film 14 is a TaNb film;

FIG. 7 is a diagram illustrating an optimal area of the complex refractive index of the antireflective film 15 when the absorber film 14 is a TaN film;

FIG. 8 is a schematic cross-sectional diagram illustrating another embodiment of the reflective mask blank for EUVL of the present invention;

FIGS. 9A to 9D are diagrams illustrating a procedure for manufacturing the reflective mask for EUVL of the present invention;

FIG. 10A is a diagram showing results of simulations in the case of employing a RuO₂ film for the absorber film provided thereon with a TaAl film having a film thickness of 2 nm as the antireflective film and in the case of employing the RuO₂ film without the TaAl film, illustrating a relationship between the film thickness and the reflectance of the absorber film;

FIG. 10B is a diagram illustrating a relationship between the film thickness and the phase shift amount of the absorber film;

FIG. 11A is a diagram showing results of simulations in the case of employing a TaNb film for the absorber film provided thereon with a TaAl film having a film thickness of 2 nm as the antireflective film and in the case of employing the TaNb film without the TaAl film, illustrating a relationship between the film thickness and the reflectance of the absorber film;

FIG. 11B is a diagram illustrating a relationship between the film thickness and the phase shift amount of the absorber film;

FIG. 12A is a diagram showing results of simulations in the case of employing a TaN film for the absorber film provided thereon with a TaAl film having a film thickness of 2 nm as the antireflective film, and in the case of employing the TaN film for the absorber film provided thereon with a TaON film having a film thickness of 4 nm that is used for an antireflective film for inspection light, illustrating a relationship between the film thickness and the reflectance of the absorber film;

FIG. 12B is a diagram illustrating a relationship between the film thickness and the phase shift amount of the absorber film;

FIG. 13A is a diagram showing results of simulations in the case of employing a RuO₂ film for the absorber film provided thereon with a TaAl film having a film thickness of 9 nm as the antireflective film and in the case of employing the RuO₂ film without the TaAl film, illustrating a relationship between the film thickness and the reflectance of the absorber film;

FIG. 13B is a diagram illustrating a relationship between the film thickness and the phase shift amount of the absorber film;

FIG. 14A is a diagram showing results of simulations in the case of employing a TaNb film for the absorber film provided thereon with a TaAl film having a film thickness of 9 nm as the antireflective film and in the case of employing the TaNb film without the TaAl film, illustrating a relationship between the film thickness and the reflectance of the absorber film;

FIG. 14B is a diagram illustrating a relationship between the film thickness and the phase shift amount of the absorber film;

FIG. 15A a diagram showing results of simulations in the case of employing a TaN film for the absorber film provided thereon with a TaAl film having a film thickness of 2 nm as the antireflective film, and in the case of employing the TaN film for the absorber film provided thereon with a TaON film having a film thickness of 4 nm that is used for an antireflective film for inspection light, illustrating a relationship between the film thickness and the reflectance of the absorber film;

FIG. 15B is a diagram illustrating a relationship between the film thickness and the phase shift amount of the absorber film;

FIG. 16 is a diagram illustrating an optimal area and a semi-optimal area of the complex refractive index of the antireflective film 15 when the absorber film 14 is a RuN film;

FIG. 17A is a diagram showing results of simulations in the case of employing a RuN film for the absorber film provided thereon with a Cr₂O₃ film having a film thickness of 2 nm as the antireflective film and in the case of employing the RuN film without the Cr₂O₃ film, illustrating a relationship between the film thickness and the reflectance of the absorber film; and

FIG. 17B is a diagram illustrating a relationship between the film thickness and the phase shift amount of the absorber film.

### DESCRIPTION OF EMBODIMENTS

In the following, the reflective mask blank according to the present invention and the reflective mask according to the present invention will be described with reference to the drawings. In the present invention, a numerical value range expressed using “to” or “-” includes the upper limit value and the lower limit value.

### Reflective Mask Blank for EUVL

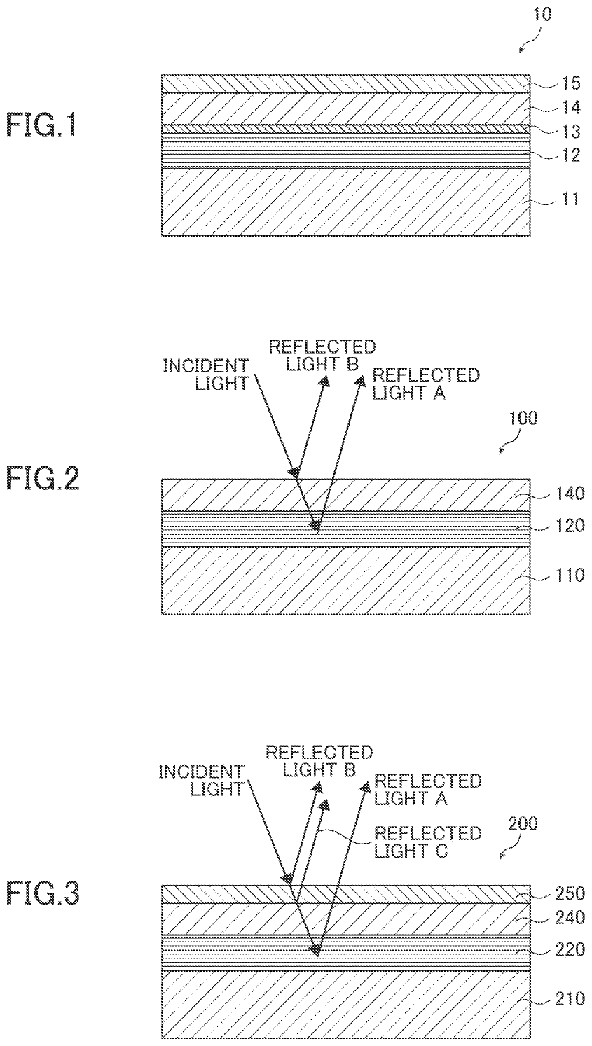

FIG. 1 is a schematic cross-sectional diagram illustrating one embodiment of the reflective mask blank for EUVL of the present invention. In a reflective mask blank for EUVL 10 shown in FIG. 1, a multilayer reflective film 12 that reflects EUV light; a protective film 13 for the multilayer reflective film 12; an absorber film 14 that absorbs EUV light; and an antireflective film 15 are formed on a substrate 11 in this order. However, among the constituent elements illustrated in the configuration shown in FIG. 1, in the reflective mask blank for EUVL of the present invention, the substrate 11, the multilayer reflective film 12, the absorber film 14, and the antireflective film 15 are essential, and the protective film 13 is optional. The protective film 13 for the multilayer reflective film 12 is provided for protecting the multilayer reflective film 12 from etching when forming a mask pattern on the absorber film 14.

Respective constituent elements of the reflective mask blank for EUVL 10 will be described below.

### Substrate

The substrate 11 preferably has a low coefficient of thermal expansion. With the low coefficient of thermal expansion of the substrate, it is possible to suppress an occurrence of distortion in a pattern formed on the absorber film caused by heat when the substrate is irradiated with EUV light. Specifically, at a temperature of 20° C., the coefficient of thermal expansion of the substrate is preferably within a range of 0±0.05×10⁻⁷/° C., and more preferably within a range of 0±0.03×10⁻⁷/° C.

For a material having a low coefficient of thermal expansion, for example, SiO₂—TiO₂-based glass may be used. The SiO₂—TiO₂-type glass is preferably quartz glass containing 90-95 wt % of SiO₂ and 5-10 wt % of TiO₂. When the content of TiO₂ is 5-10 wt %, the linear expansion coefficient at around a room temperature is almost zero, and there is little dimensional change at around the room temperature. In addition, the SiO₂—TiO₂ glass may contain a trace component other than SiO₂ and TiO₂.

The first main surface of the substrate 11 on which the multilayer reflective film 12 is laminated preferably has a high surface smoothness. The surface smoothness of the first main surface can be assessed by a surface roughness. As the surface roughness of the first main surface, a root mean square roughness Rq is preferably 0.15 nm or less. The surface smoothness can be measured by an atomic force microscope.

The first main surface is preferably subjected to surface processing to have a predetermined flatness. With the predetermined flatness of the first main surface, the reflective mask can provide a high pattern transfer accuracy and a position accuracy. The flatness in a predetermined area (e.g. 132 mm×132 mm) on the first main surface of the substrate 11 is preferably 100 nm or less, more preferably 50 nm or less, and even more preferably 30 nm or less.

Moreover, the substrate 11 is preferably resistant to a cleaning liquid used for cleaning the reflective mask blank for EUVL, a reflective mask for EUVL after patterning, or the like. The substrate 11 preferably has a high rigidity to suppress deformation of the substrate 11 caused by film stress by films formed on the substrate 11 (multilayer reflective film 12, absorber film 14, or the like). For example, a Young's modulus of the substrate 11 is preferably 65 GPa or more.

### Multilayer Reflective Film

The multilayer reflective film 12 has a high reflectance for EUV light. Specifically, when the EUV light enters the surface of the multilayer reflective film at an incident angle of 6 degrees, the maximum reflectance of EUV light is preferably 60% or more, and more preferably 65% or more. Similarly, even when the protective film 13 is laminated on the multilayer reflective film 12, the maximum reflectance of EUV light is preferably 60% or more, and more preferably 65% or more.

The multilayer reflective film 12 is a multilayer film, in which a plurality of layers including elements having different refractive indices as main components are periodically laminated. A multilayer reflective film is generally obtained by alternately laminating from a substrate side a high refractive index film having a high refractive index for EUV light and a low refractive index film having a low refractive index for EUV light.

The multilayer reflective film 12 may have a multilayer structure in a plurality of periods including lamination structures, each having the high refractive index film and the low refractive index film laminated in this order from the substrate side as a single grouping. Alternatively, the multilayer reflective film 12 may have a multilayer structure in a plurality of periods including lamination structures, each having the low refractive index film and the high refractive index film laminated in this order from the substrate side as a single period. In this case, an outermost layer (uppermost layer) of the multilayer reflective film is preferably the high refractive index film. This is because when the low refractive index film is used for the uppermost layer of the multilayer reflective film, the low refractive index film is readily oxidized, and the reflectance of the multilayer reflective film is reduced.

For the high refractive index film, a film containing silicon (Si) may be used. A material containing Si includes, in addition to silicon alone, a Si compound containing one or more species selected from the group consisting of boron (B), carbon (C), nitrogen (N), and oxygen (O) added to Si. By using the high refractive index film containing Si, a reflective mask with an excellent reflectance for EUV light is obtained. For the low refractive index film, a metal selected from the group consisting of molybdenum (Mo), ruthenium (Ru), rhodium (Rh), and platinum (Pt), or an alloy thereof may be used. The reflective mask blank according to the present invention preferably has the low refractive index film containing Mo, and the high refractive index film containing Si. In this case, when the high refractive index film (Si film) is used for the uppermost layer of the multilayer reflective film, a silicon oxide film including Si and O is formed between the uppermost layer (Si film) and the protective film 13, so that the cleaning resistance of the reflective mask blank can be improved.

The thickness of each layer and the number of periods of the lamination structures of the layers in the multilayer reflective film 12 can be suitably selected according to the film material to be used, the reflectance for EUV light required for the multilayer reflective film 12, the wavelength (exposure wavelength) of the EUV light, or the like. For example, in the case where the multilayer reflective film 12 is required to have the maximum reflection value of 60% or more for the EUV light, a Mo/Si multilayer reflective film, in which a low refractive index film (Mo film) and a high refractive index film (Si film) are alternately laminated in 30 to 60 periods, is preferably used.

Each layer in the multilayer reflective film 12 can be formed to have a desired thickness using a publicly-known film forming method, such as a magnetron sputtering method or an ion beam sputtering method. For example, when the multilayer reflective film is prepared using the ion beam sputtering method, the high refractive index film and the low refractive index film are formed by supplying ion particles from an ion source to a target of a high refractive index material and a target of a low refractive index material. When the multilayer reflective film 12 is a Mo/Si multilayer reflective film, for example, a Si film with a predetermined thickness is formed on a substrate by the ion beam sputtering method using a Si target. Then, a Mo film with a predetermined thickness is formed using a Mo target. A lamination structure having the Si film and the Mo film, as a single period, is periodically laminated in 30 to 60 periods, to form the Mo/Si multilayer reflective film.

### Protective Film

The protective film 13 protects the multilayer reflective film, suppressing damage on the surface of the multilayer reflective film 12 caused by etching when a pattern is formed by etching (typically dry etching) the absorber film 14, during manufacturing of the reflective mask, which will be described below. In addition, the protective film 13 protects the multilayer reflective film from the cleaning liquid, when cleaning the reflective mask by removing a resist film remaining in the reflective mask after etching using the cleaning liquid. Thus, the reflectance of the resulting reflective mask for the EUV light is excellent. FIG. 1 shows the case where the protective film 13 is a single layer. However, the protective film 13 may include a plurality of layers.

For the material for forming the protective film 13, a material less liable to be damaged due to etching when the absorber film 14 is etched is selected. Suitable materials satisfying the above-described condition include, for example, Ru-based materials such as Ru metal alone, Ru alloys containing one or more metals selected from the group consisting of Si, titanium (Ti), niobium (Nb), Rh, tantalum (Ta), and zirconium (Zr) in Ru, nitrides containing nitrogen in Ru alloys; Cr, aluminum (Al), and Ta metals alone, and nitrides containing nitrogen in the metals; and SiO₂, Si₃N₄, Al₂O₃, and mixtures thereof. Among them, Ru metal alone and Ru alloy, CrN and SiO₂ are preferably used. Ru metal alone and Ru alloys are particularly preferred because they are unlikely to be etched by oxygen-free gases and function as etch stoppers during etching of the absorber film 14.

When the protective film 13 is formed of a Ru alloy, the Ru content of the Ru alloy is preferably 30 at % or more and less than 100 at %. If the Ru content is within the above-described range, when the multilayer reflective film 12 is a Mo/Si multilayer reflective film, it is possible to suppress diffusion of Si from the Si layer to the protective film 13 in the multilayer reflective film 12. Moreover, the protective film 13 functions as an etch stopper during etching of the absorber film 14 while maintaining sufficient reflectance for EUV light. Furthermore, with the protective film 13, it is possible to improve the cleaning resistance of the reflective mask and suppress age deterioration of the multilayer reflective film 12.

The thickness of the protective film 13 is not particularly limited as long as the protective film can perform the function required for the protective film 13. In terms of maintaining the reflectance for the EUV light reflected by the multilayer reflective film 12, the thickness of the protective film 13 is preferably 1 to 8 nm, more preferably 1.5 to 6 nm, and even more preferably 2 to 5 nm.

### Absorber Film

When the reflective mask for EUVL is used as a binary mask, the reflectance for EUV light of the absorber film 14 is required to be low in order to absorb EUV light. Specifically, when the surface of the absorber film 14 is irradiated with EUV light with a wavelength of about 13.5 nm, the maximum reflectance for the EUV light is preferably 2% or less. The above-described absorber film 14 for the binary mask preferably includes one or more metals selected from the group consisting of Ta, Ti, tin (Sn), and Cr. Among the metals, Ta is more preferable. The absorber film 14 for the binary mask may contain one or more elements selected from the group consisting of O, N, B, hafnium (Hf), and hydrogen (H) in addition to the above-described metals. Among the above-described elements, the absorber film 14 preferably includes O and N or B, and more preferably includes N or B. By including N or B, it is possible to change a crystalline state of the absorber film 14 to an amorphous state or a microcrystal state. With the above-described features, the surface smoothness and the flatness of the absorber film 14 are improved. With the improved surface smoothness and flatness of the absorber film 14, an edge roughness of the absorber film pattern of the reflective mask for EUVL is reduced, and dimensional accuracy is improved.

Furthermore, when the reflective mask for EUVL is used as the phase shift mask, the reflectance for EUV light of the absorber film 14 is required to be 2% or more. In order to obtain sufficient phase shift effect, the reflectance is preferably 9% to 15%. When the phase shift mask is used, contrast of an optical image on a wafer is improved, and an exposure margin is increased.

Materials for forming the above-described absorber film 14 for the phase shift mask include, for example, Ru metal alone, Ru alloys containing one or more metals selected from the group consisting of Cr, gold (Au), Pt, rhenium (Re), Hf, Ta, and Ti in Ru, and an alloy of Ta and Nb. Ru metal alone, Ru alloys, or alloy of Ta and Nb may be an oxide containing oxygen, a nitride containing nitrogen, an oxynitride containing oxygen and nitrogen, or a boride containing boron. Among the above-described materials, Ru, TaNb alloys, or oxides, nitrides, oxynitrides, and borides thereof are preferably used, and RuO₂, TaNb alloys are more preferably used.

Moreover, the absorber film 14 also may include, for example, one or more metals selected from the group consisting of Ru, Cr, gold (Au), tin (Sn), Pt, rhenium (Re), Hf, Ta, and Ti, and preferably include one or more metals selected from the group consisting of Ta, Ti, Sn, and Cr. Furthermore, the absorber film 14 may include one or more components selected from the group consisting of O, N, B, hafnium (Hf), and hydrogen (H).

The absorber film 14 is subjected to a pattern formation by dry etching using a Cl-based gas including Cl or an F-based gas including F, regardless of whether the reflective mask for EUVL is a binary mask or a phase shift mask. Therefore, the absorber film is required to be readily etched by the above-described dry etching. Any of the above-described absorber films for the binary mask and the above-described absorber films for the phase shift mask can be readily etched by the above-described dry etching.

Moreover, the absorber film 14 is exposed to the cleaning liquid when the resist pattern remaining in the reflective mask blank after etching is removed by the cleaning liquid during manufacturing of the reflective mask for EUVL, which will be described later. In this case, as the cleaning liquid, sulfuric acid hydrogen peroxide mixture (SPM), sulfuric acid, ammonia, ammonia hydrogen peroxide mixture (APM), hydroxyl radical cleaning water, ozone water, or the like is used. In the EUVL, SPM is commonly used as the cleaning liquid for removing the resist. SPM is a solution obtained by mixing sulfuric acid and hydrogen peroxide. For example, the SPM is a solution obtained by mixing sulfuric acid and hydrogen peroxide in a volume ratio of 3:1. In this case, the temperature of the SPM is preferably controlled to be 100° C. or higher in order to enhance the etching rate. Therefore, the absorber film 14 needs to have cleaning resistance against the cleaning liquid. Both the above-described absorber film for the binary mask and the above-described absorber film for the phase shift mask have high cleaning resistance against the above-described cleaning liquid.

The absorber film 14 may be a single layer film or a multilayer film including a plurality of films. When the absorber film 14 is a single layer film, the number of processes for manufacturing the mask blank can be reduced, and the production efficiency is improved. When the absorber film 14 is a multilayer film, by adjusting appropriately the optical constant or the film thickness of the uppermost layer of the absorber film 14, the absorber film 14 can be used as an antireflective film for inspection light when inspecting the pattern of the absorber using inspection light (wavelength 248 to 193 nm). Thus, the inspection sensitivity during the inspection of the absorber pattern is enhanced.

The absorber film 14 can be formed using publicly-known film forming methods, such as a magnetron sputtering method or an ion beam sputtering method. For example, when a ruthenium oxide film (RuO₂ film) is formed as the absorber film 14 by the magnetron sputtering method, the absorber film 14 can be formed by a sputtering method using a Ru target; and using Ar gas and oxygen gas. When a TaNb film is formed using the magnetron sputtering method as the absorber film 14, the absorber film 14 can be formed by a sputtering method using a Ta target and a Nb target, or a target including Ta and Nb; and using Ar gas. When the TaN film is formed using the magnetron sputtering method as the absorber film 14, the absorber film 14 can be formed by a sputtering method using a Ta target; and using Ar gas and nitrogen gas.

For any of the absorber film for a binary mask and the absorber film for a phase shift mask, the film thickness of the absorber film 14 is preferably 20 to 80 nm, more preferably 30 to 70 nm, and even more preferably 40 to 60 nm.

### Antireflective Film

An antireflective film 15 is provided to suppress reflection of EUV light at the surface of absorber film 14. The optimum film thickness d of the antireflective film is determined by Equation (5).

$$\begin{matrix}[ Math 8 ] & \\ Arg ( {r}_{B} ) + \frac{4 π}{λ} {n}^{′} d - Arg ( {r}_{C} ) = ( 2 m + 1 ) π . & ( 5 )\end{matrix}$$

where λ in Equation (5) is a wavelength, and m is an integer greater than or equal to 0. In view of the film thickness controllability, a thin film is preferable, which corresponds to the case where m=0 or 1 in Equation (5). Then, the optimal film thickness d of the antireflective film 15 is approximately λ/4 or 3λ/4. The above-described thicknesses correspond to film thicknesses of 2 to 5 nm and 8 to 12 nm.

The material of the antireflective film 15 preferably satisfies Equation (6).

$$\begin{matrix}[ Math 9 ] & \\ - 0.02 < \frac{( \sqrt{{( n - {n}^{′} )}^{2} + {( k - {k}^{′} )}^{2}} - \sqrt{{( 1 - {n}^{′} )}^{2} + {k}^{{′}^{2}}} )}{2} < 0.02 & ( 6 )\end{matrix}$$

In Equation (6), n and k represent the refractive index and the extinction coefficient of the absorber film 14 at the EUV light wavelength, respectively, and n′ and k′ represent the refractive index and the extinction coefficient of the antireflective film 15 at the EUV light wavelength, respectively.

Thus, the optimal value of the complex refractive index (refractive index and extinction coefficient) of the antireflective film 15 depends on the complex refractive index of the absorber film 14.

The material of the antireflective film 15 more preferably satisfies Equation (7).

$$\begin{matrix}[ Math 10 ] & \\ - 0.01 < \frac{( \sqrt{{( n - {n}^{′} )}^{2} + {( k - {k}^{′} )}^{2}} - \sqrt{{( 1 - {n}^{′} )}^{2} + {k}^{{′}^{2}}} )}{2} < 0.01 & ( 7 )\end{matrix}$$

In Equation (7), n and k represent the refractive index and the extinction coefficient of the absorber film 14 at the EUV light wavelength, respectively, and n′ and k′ represent the refractive index and the extinction coefficient of the antireflective film 15 at the EUV light wavelength, respectively.

Thus, the optimal value of the complex refractive index (refractive index and extinction coefficient) of the antireflective film 15 depends on the complex refractive index of the absorber film 14.

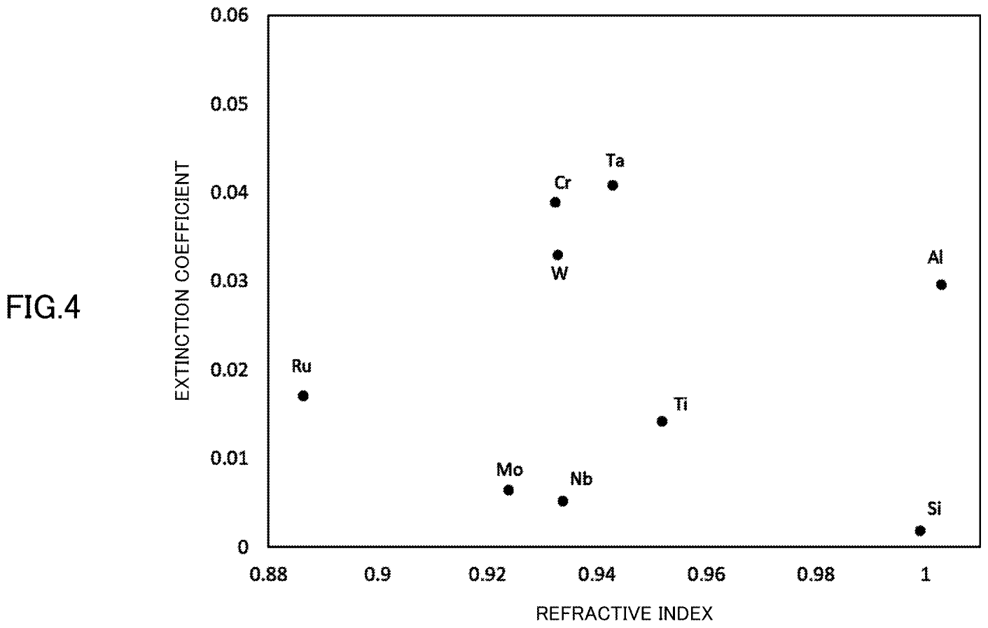

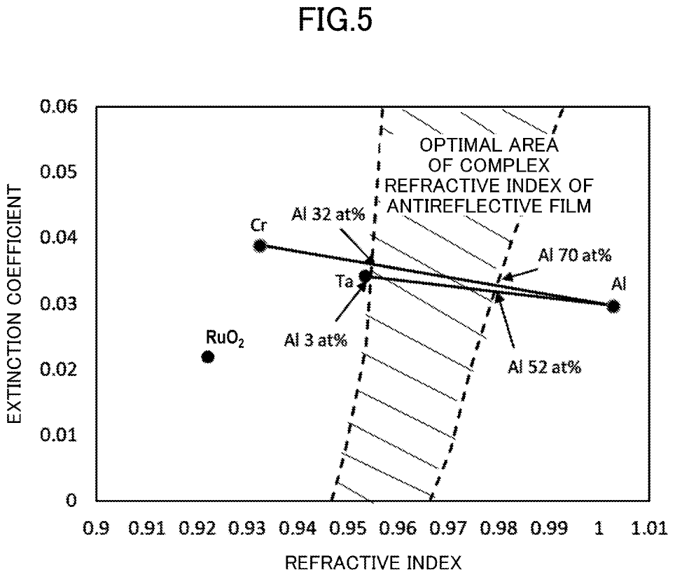

The same cleaning resistance as that of the absorber film 14 is required for the antireflective film 15. Suitable metals with good cleaning resistance include, for example, Ta, Cr, Ti, Nb, Mo, W, and Ru. FIG. 4 shows complex refractive indices of Ta, Cr, Ti, Nb, Mo, W, and Ru. As shown in FIG. 4, these metals alone do not fall within the optimal area of complex refractive indices for the antireflective film 15.

As shown in FIG. 4, Al has the complex refractive index of (n,k)=(1.00,0.030). Al also has good cleaning resistance. Therefore, Al can be used as the antireflective film 15 by preparing an alloy with at least one metallic element selected from the group consisting of Ta, Cr, Ti, Nb, Mo, W, and Ru.

FIG. 5 shows the optimal area of the complex refractive index of the antireflective film 15 when the absorber film 14 is a RuO₂ film. When an aluminum alloy containing Ta and Al is selected as the antireflective film 15, the complex refractive index falls within the optimal area if the Al content is 3 to 52 at %. When an aluminum alloy containing Cr and Al is selected as the antireflective film 15, the complex refractive index falls within the optimal area if the Al content is 32 to 70 at %.

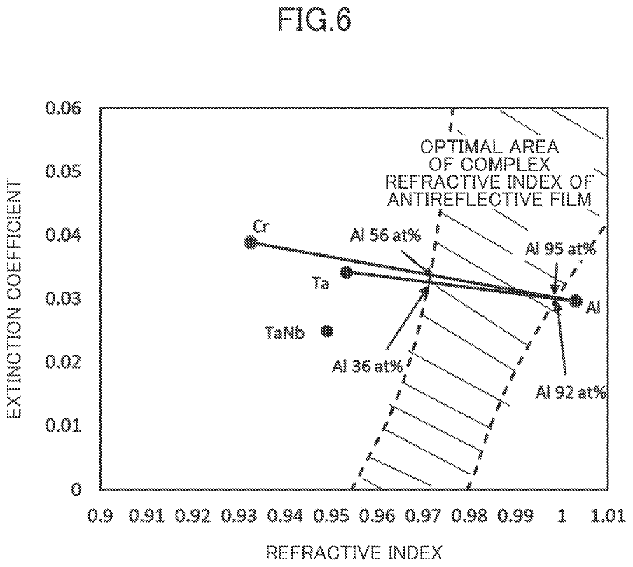

FIG. 6 shows the optimal area of the complex refractive index of the antireflective film 15 when the absorber film 14 is a TaNb film. When an aluminum alloy containing Ta and Al is selected as the antireflective film 15, the complex refractive index falls within the optimal area if the Al content is 36 to 92 at %. When an aluminum alloy containing Cr and Al is selected as the antireflective film 15, if the Al content is 56 to 95 at %, the complex refractive index falls within the optimal area.

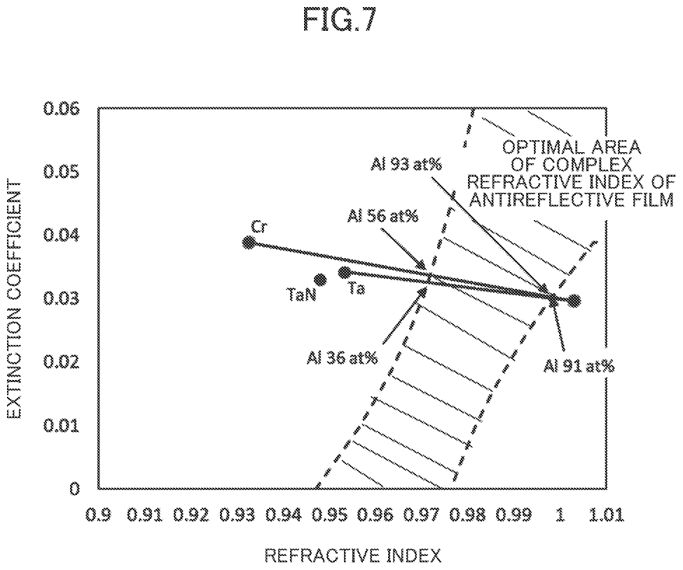

FIG. 7 shows the optimal area of the complex refractive index of the antireflective film 15 when the absorber film 14 is TaN. When an aluminum alloy containing Ta and Al is selected as the antireflective film 15, the complex refractive index falls within the optimal area if the Al content is 36 to 91 at %. When an aluminum alloy containing Cr and Al is selected as the antireflective film 15, if the Al content is 56 to 93 at %, the complex refractive index falls within the optimal area.

Thus, for an aspect of the antireflective film 15, an aluminum alloy containing Al and at least one metallic element selected from the group consisting of Ta, Cr, Ti, Nb, Mo, W, and Ru may be used. The Al content in the aluminum alloy is preferably 3 to 95 at %, more preferably 20 to 80 at %, and even more preferably 30 to 60 at %.

The aluminum alloy used in the antireflective film 15 may further include at least one element (X) selected from the group consisting of O, N, and B. By including the above-described element (X), the crystal state of the antireflective film 15 can be changed to an amorphous state. Thus, the cleaning stability of the antireflective film 15 can be improved. The complex refractive index of the aluminum alloy containing the element (X) differs from the complex refractive index of the aluminum alloy without the element (X), but an amount of deviation is small. Therefore, if an aluminum alloy having the same composition ratio without the element (X) as the composition ratio of the above-described aluminum alloy is used, the complex refractive index of the aluminum alloy falls within the optimal area for the antireflective film 15.

When an aluminum alloy containing the element (X) is used, the Al content in the aluminum alloy excluding the element (X) is preferably 3 to 95 at %, more preferably 20 to 80 at %, and even more preferably 30 to 60 at %.

When the aluminum alloy containing the element (X) is used, the total content of the element (X) is preferably 97 at % or less, more preferably 90 at % or less, and even more preferably 80 at % or less.

The lower limit of the total content of the element (X) is not particularly limited, but is preferably 5 at % or more.

Japanese Unexamined Patent Application Publication No. 2011-35104 describes an example in which a low reflection layer is formed on an absorber layer for inspection light (wavelength: 190 to 260 nm) for a mask pattern and the low reflection layer includes Al, Zr, or both, and includes O N, or both. However, the low reflection layer is for the inspection light (wavelength: 190 to 260 nm) for the mask pattern and does not function as an antireflective film for EUV light.

For another aspect of the antireflective film 15, the reflective mask blank for EUVL may be formed of a material that satisfies above-described Equation (6). For example, the antireflective film 15 may include at least one metallic element selected from the group consisting of Al, Ta, Cr, Ti, Nb, Mo, W, and Ru, and may further include at least one element (Y) selected from the group consisting of O, N, B, Hf, and H.

Moreover, for the above-described other aspect of the antireflective film 15, the antireflective film 15 may include an aluminum alloy contains Al and at least one metallic element selected from the group consisting of Ta, Cr, Ti, Nb, Mo, W, and Ru, and may further contain the above-described element (Y).

An Al content in the aluminum alloy excluding the element (Y) is preferably 3 to 95 at %, more preferably 20 to 80 at %, and even more preferably 30 to 60 at %.

When the aluminum alloy containing the element (Y) is used, the total content of the element (Y) is preferably 97 at % or less, more preferably 90 at % or less, and even more preferably 80 at % or less.

The lower limit of the total content of the element (Y) is not particularly limited, but is preferably 5 at % or more.

The antireflective film 15 can be formed using publicly-known film forming methods such as the magnetron sputtering method or the ion beam sputtering method. For example, when an aluminum alloy film containing Ta and Al, as the antireflective film 15, is formed using the magnetron sputtering method, the antireflective film 15 can be formed by the sputtering method using Ar gas and using a Ta target and an Al target or a target including Ta and Al.

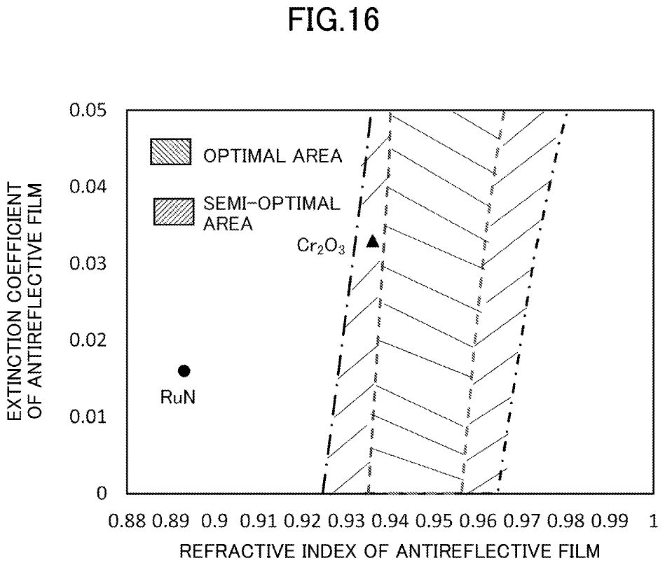

FIG. 16 shows the optimal area and the semi-optimal area of the complex refractive index of the antireflective film 15 when the absorber film 14 is a RuN film. When Cr₂O₃ is selected as the antireflective film 15, the complex refractive index of the antireflective film 15 does not fall within the optimal area (area that satisfies Equation (7)) but falls within the semi-optimal area (area that satisfies Equation (6)).

According to the reason explained above using Equation (5), the thickness of the antireflective film 15 is preferably 2 to 5 nm, or 8 to 12 nm.

### Hard Mask

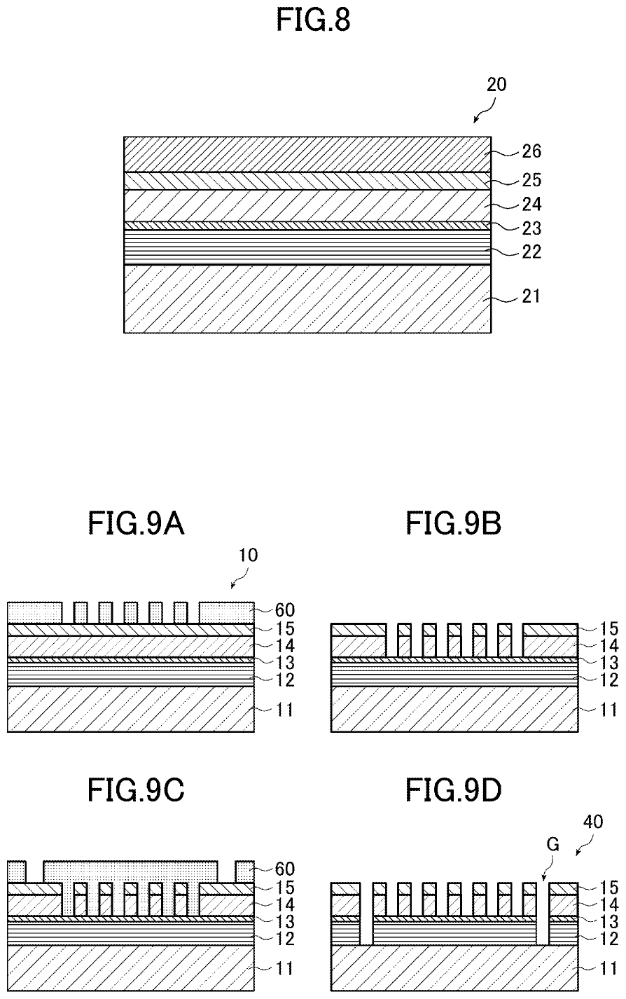

FIG. 8 is a schematic cross-sectional view of another configuration example of the reflective mask blank for EUVL according to the present invention. In the reflective mask blank for EUVL 20 shown in FIG. 8, a multilayer reflective film 22, a protective film 23, an absorber film 24, an antireflective film 25, and a hard mask film 26 are formed in this order on the substrate 21.

Among the above-described constituent elements of the reflective mask blank for EUVL 20, the substrate 21, the multilayer reflective film 22, the protective film 23, the absorber film 24, and the antireflective film 25 are the same as those of the reflective mask blank for EUVL 10 described above and explanations thereof will be omitted.

The hard mask film 26 is made of a material that is highly resistant to the etching process for the absorber film 24 and the antireflective film 25, such as a Cr-based film containing Cr or a Si-based film containing Si. The Cr-based film is, for example, made of Cr alone or a material in which O or N is added to Cr. Specifically, the material includes CrO or CrN. The Si-based film is, for example, made of Si alone or a material containing one or more species selected from the group consisting of O, N, C, and H added to Si. Suitable materials include, specifically, SiO₂, SiON, SiN, SiO, Si, SiC, SiCO, SiCN, and SiCON. With the hard mask film 26 formed on the antireflective film 25, dry etching can be performed even when a minimum linewidth of the absorber film pattern and the antireflective film pattern is small. Therefore, it is effective for refining the pattern of the absorber film.

The thickness of the hard mask film 26 is preferably 3 to 20 nm, more preferably 4 to 15 nm, and even more preferably 5 to 10 nm.

The above-described hard mask film 26 can be formed by performing publicly-known film forming methods, such as the magnetron sputtering method, or the ion beam sputtering method.

The reflective mask blank for EUVL 10 according to the present invention may be provided with a functional coating which is known in the field of mask blanks for EUVL, in addition to the multilayer reflective film 12, the protective film 13, the absorber film 14, and the antireflective film 15. Moreover, the reflective mask blank for EUVL 20 according to the present invention may be provided with a functional coating which is known in the field of mask blanks for EUVL, in addition to the multilayer reflective film 22, the protective film 23, the absorber film 24, the antireflective film 25 and the hard mask film 26.

### Rear Face Conductive Film

The reflective mask blank for EUVL 10 according to the present invention may be provided with a rear face conductive film for an electrostatic chuck on a second major surface of the substrate 11 opposite to the side where the multilayer reflective film 12 is laminated. The rear face conductive film is required to have a low sheet resistance value. For example, the sheet resistance value of the rear face conductive film is preferably 200 Ω/□ or less.

For the material forming the rear face conducting film, for example, metals such as Cr or Ta, or alloys thereof may be used. For the alloy containing Cr, a Cr-based material containing Cr and one or more species selected from the group consisting of B, N, O, and C may be used. Suitable Cr-based materials include, for example, CrN, CrON, CrCN, CrCON, CrBN, CrBON, CrBCN, and CrBOCN. For the alloy containing Ta, a Ta-based material containing Ta and one or more species selected from the group consisting of B, N, O, and C may be used. Suitable Ta-based materials include, for example, TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, and TaSiCON.

The thickness of the rear face conductive film is not particularly limited as long as the rear face conductive film satisfies the function for an electrostatic chuck. The thickness is, for example, 10 to 400 nm. The rear face conductive film can also be provided with a function of adjusting stress on the second main surface side of the reflective mask blank. That is, the rear face conductive film can adjust stresses from the respective layers formed on the first main surface side, so that the reflective mask blank has a flat surface.

### Reflective Mask and Method of Manufacturing Reflective Mask

An example of a reflective mask for EUVL and a method of manufacturing the reflective mask for EUVL will be described with reference to FIGS. 9A to 9D. FIGS. 9A to 9D illustrate the procedure for manufacturing the reflective mask for EUVL.

First, as shown in FIG. 9A, a resist film is applied on the reflective mask blank for EUVL 10. Then, the resist film is exposed and developed, to form a resist pattern 60 on the reflective mask blank for EUVL 10 corresponding to a fine pattern in a chip. Thereafter, as shown in FIG. 9B, the antireflective film 15 and the absorber film 14 are subjected to the dry etching using the resist pattern as a mask, to form an antireflective film 15 pattern and an absorber film 14 pattern. In FIG. 9B, the resist pattern has been removed. Next, as shown in FIG. 9C, the resist film is applied again on the reflective mask blank for EUVL 10. Then, the resist film is exposed to and developed, to form a resist pattern 60 corresponding to an exposure frame. Thereafter, as shown in FIG. 9D, the exposure frame G is formed by dry etching using the resist pattern 60 as a mask until the exposure frame reaches the substrate 11. According to the above-described processes, the reflective mask for EUVL 40 shown in FIG. 9D can be manufactured. In the reflective mask for EUVL 40 shown in FIG. 9D, patterns are formed on the absorber film 14 and the antireflective film 15 of the reflective mask blank for EUVL 10. Thus, the reflective mask for EUVL can be manufactured in the step of FIG. 9B. However, the reflective mask for EUVL 40 is preferably provided with the exposure frame G, as shown in FIG. 9D, in order to suppress leakage of light from adjacent shots.

### EXAMPLES

The present invention will be described in more detail with reference to examples. However, the present invention is not limited to the examples.

### Example 1

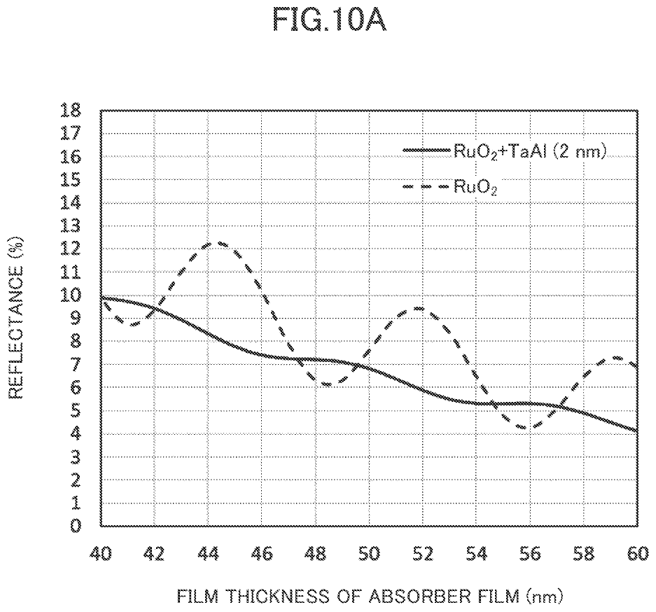

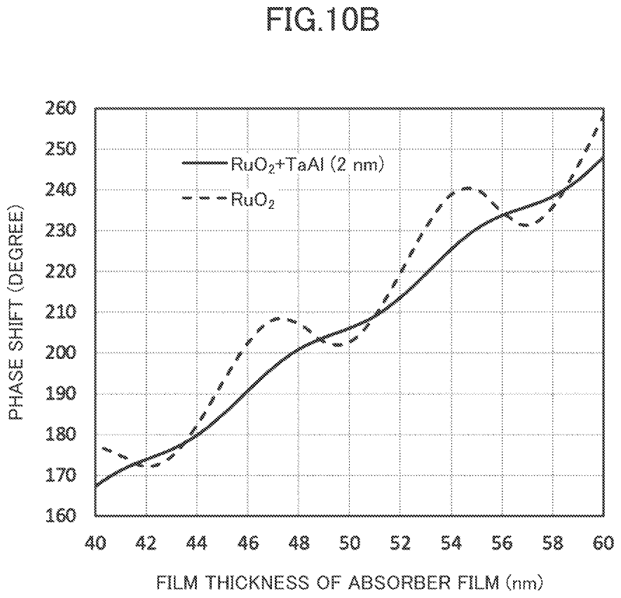

FIG. 10 shows results of simulations in which a RuO2 film was used as the absorber film and a TaAl film with a film thickness of 2 nm was provided as the antireflective film on the absorber film, and in which the TaAl film was not provided. The complex refractive index of the TaAl film was (n′,k′)=(0.967,0.033), and the Al content was 28 at %. The present simulation used a model in which a Mo/Si multilayer reflective film was used as the multilayer reflective film described in “Experimental approach to EUV imaging enhancement by mask absorber height optimization”, Proc. SPIE 8886 (2013) 8860A, and a Ru film was used as the protective film. The complex refractive index of the TaAl film satisfied Equation (5). As can be seen in FIG. 10, by providing the antireflective film, the variation in the reflectance and the phase shift amount caused by the change in the thickness of the absorber film was reduced.

### Example 2

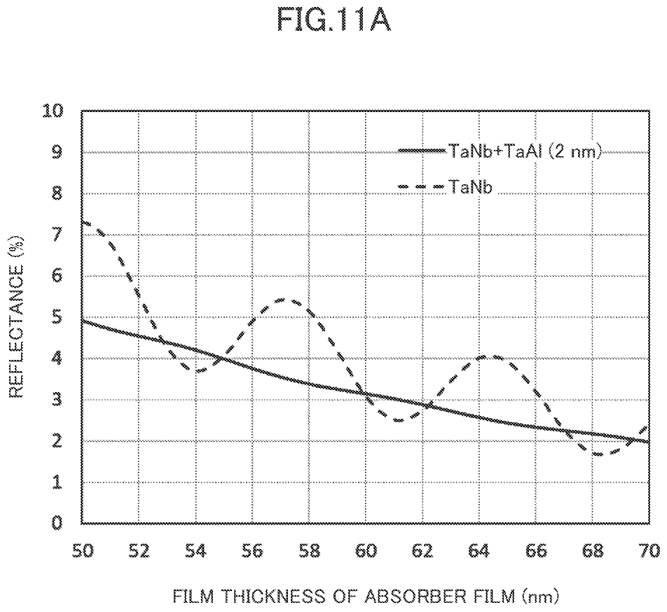

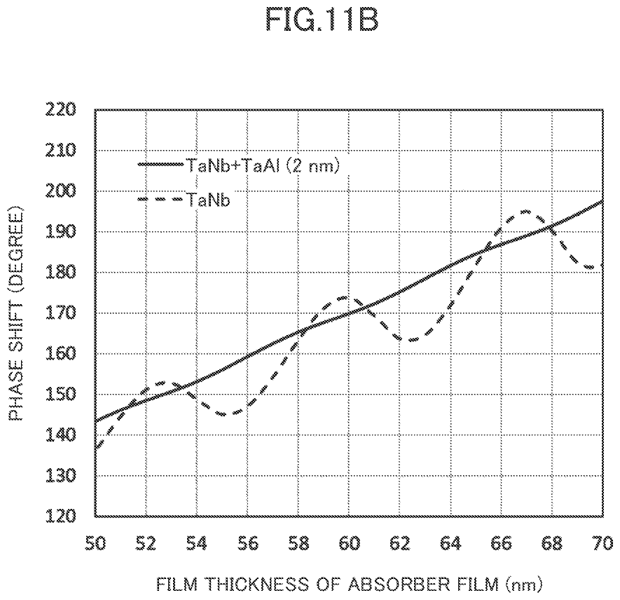

FIG. 11 shows results of simulations in which a TaNb film was used as the absorber film and a TaAl film with a film thickness of 2 nm as the antireflective film was provided on the absorber film, and in which the TaAl film was not provided. The complex refractive index of the TaAl film was (n′,k′)=(0.984,0.031) of the TaAl film, and the Al content was 61 at %. The complex refractive index of the TaAl film satisfied Equation (5). As can be seen in FIG. 11, by providing the antireflective film, the variation in the reflectance and the phase shift amount caused by the change in the thickness of the absorber film was reduced.

### Example 3

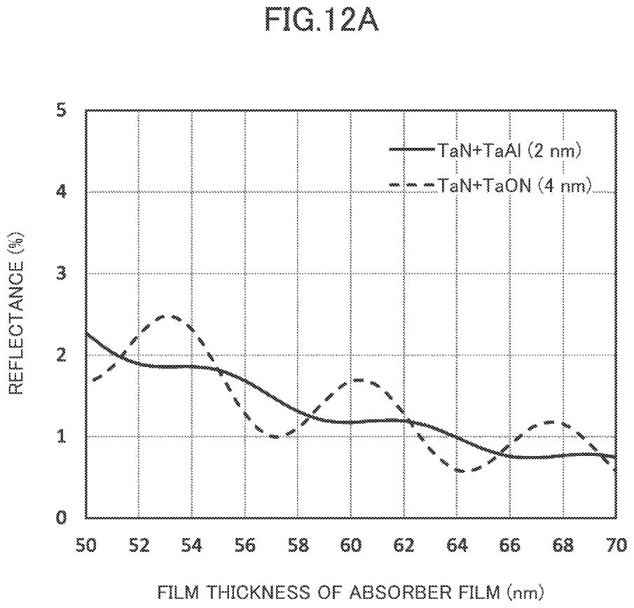

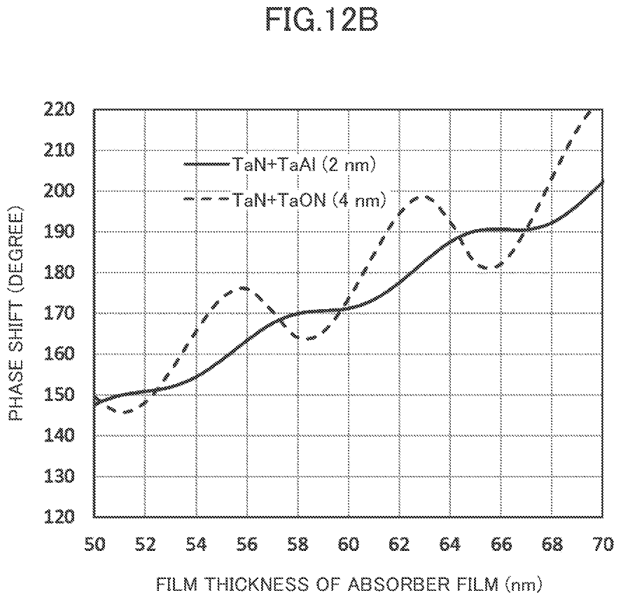

FIG. 12 shows results of simulations in which a TaN film was used as the absorber film and a TaAl film with a film thickness of 2 nm as the antireflective film was provided on the absorber film, and in which a TaON film with a film thickness of 4 nm, which was used as the antireflective film for inspection light, was provided on the absorber film. The complex refractive index of the TaN film was (n,k)=(0.948,0.033), and the complex refractive index of the TaON film was (n′,k′)=(0.955,0.025). The complex refractive index of the TaON film did not satisfy Equation (5), and the TaON film did not have the function of the antireflective film for EUV light. The complex refractive index of the TaAl film was (n′,k′)=(0.984,0.031), and the Al content was 61 at %. As can be seen in FIG. 12, by providing the antireflective film satisfying Equation (5), the variation in the reflectance and the phase shift amount caused by the change in the thickness of the absorber film was reduced.

### Example 4

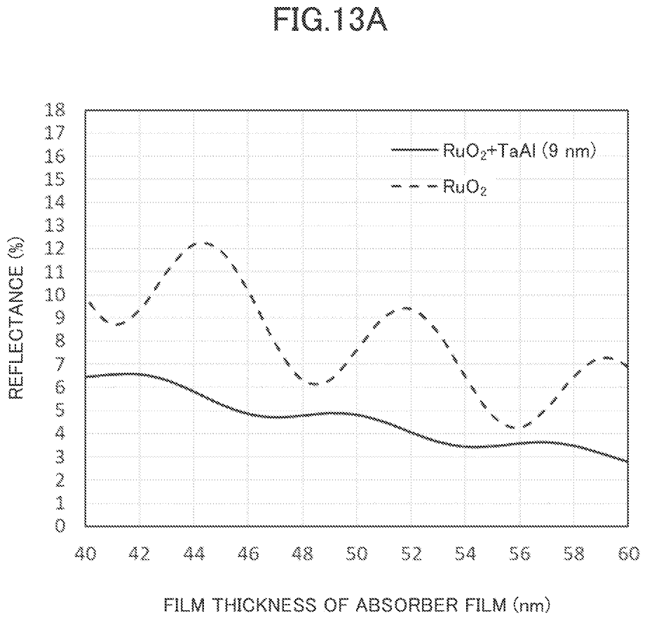

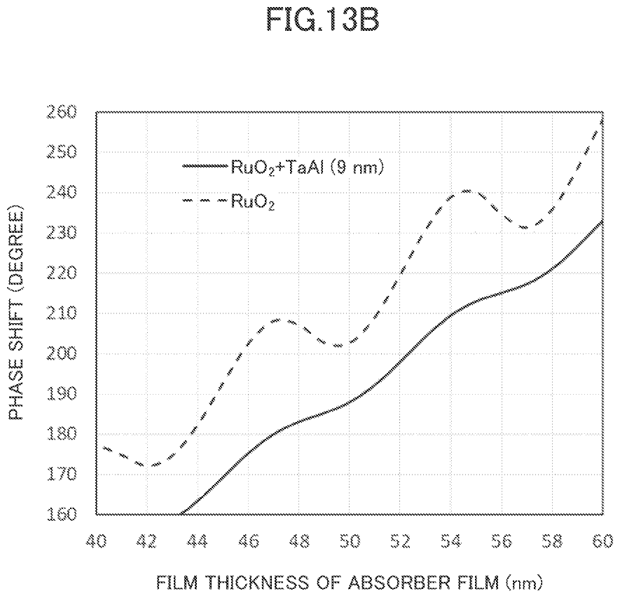

FIG. 13 shows results of simulations in which a RuO₂ film was used as the absorber film and a TaAl film with a film thickness of 9 nm was provided as the antireflective film on the absorber film, and in which the TaAl film was not provided. The complex refractive index of the TaAl film was (n′,k′) =(0.967,0.033), and the Al content was 28 at %. As can be seen in FIG. 13, by providing the antireflective film, the variation in the reflectance and the phase shift amount caused by the change in the thickness of the absorber film was reduced.

### Example 5

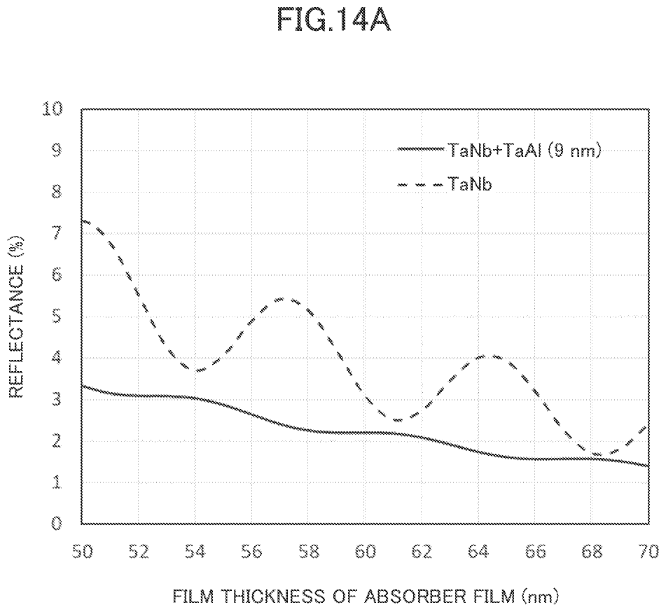

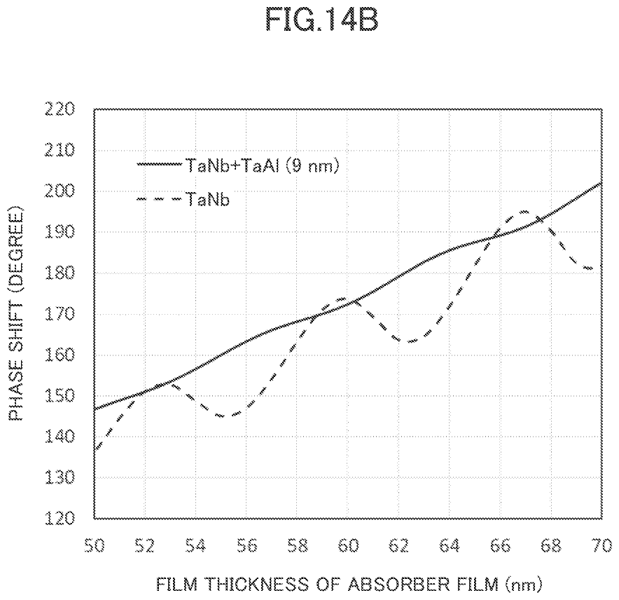

FIG. 14 shows results of simulations in which a TaNb film was used as the absorber film and a TaAl film with a film thickness of 9 nm as the antireflective film was provided on the absorber film, and in which the TaAl film was not provided. The complex refractive index of the TaAl film was (n′,k′)=(0.984,0.031), and the Al content was 61 at %. The complex refractive index of the TaAl film satisfied Equation (5). As can be seen in FIG. 14, by providing the antireflective film, the variation in the reflectance and the phase shift amount caused by the change in the thickness of the absorber film was reduced.

### Example 6

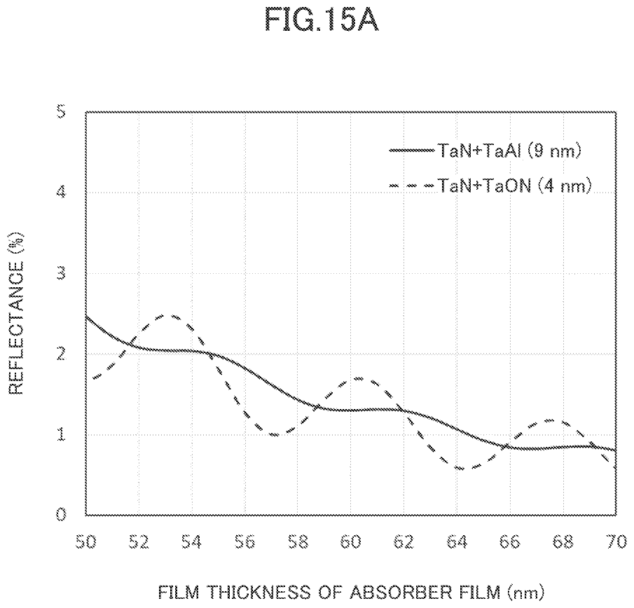

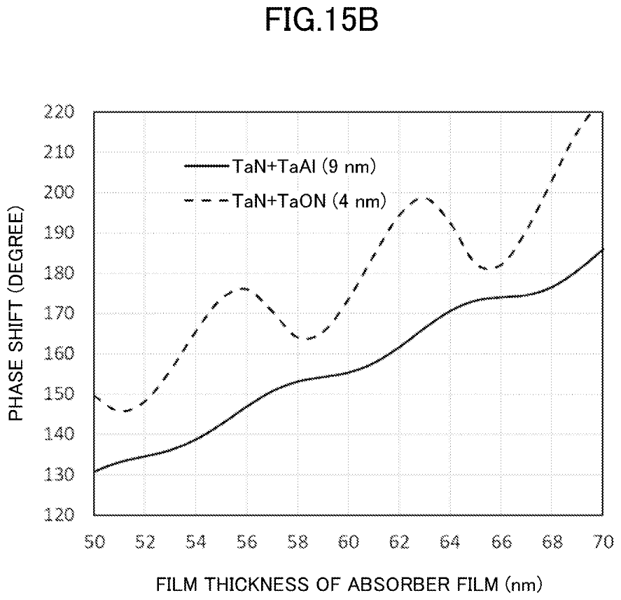

FIG. 15 shows results of simulations in which a TaN film was used as the absorber film and a TaAl film with a film thickness of 9 nm as the antireflective film was provided on the absorber film, and in which a TaON film with a film thickness of 4 nm, which was used as the antireflective film for inspection light, was provided on the absorber film. The complex refractive index of the TaAl film was (n′,k′)=(0.984,0.031), and the Al content was 61 at %. As can be seen in FIG. 15, by providing the antireflective film satisfying Equation (5), the variation in the reflectance and the phase shift amount caused by the change in the thickness of the absorber film was reduced.

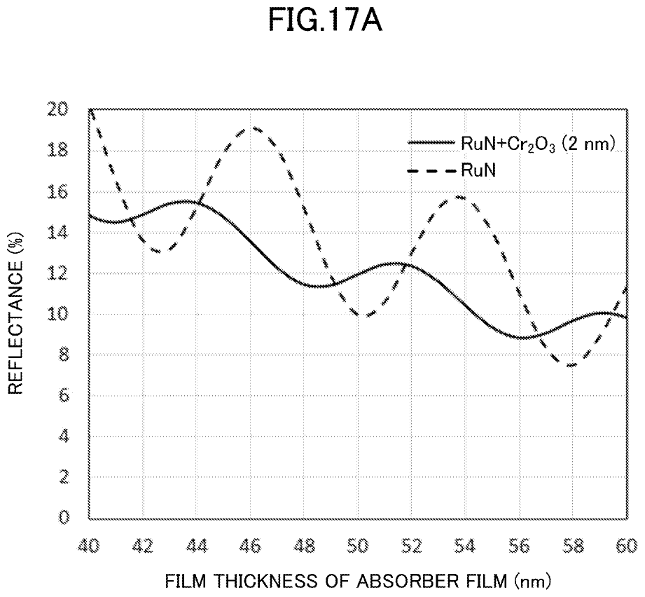

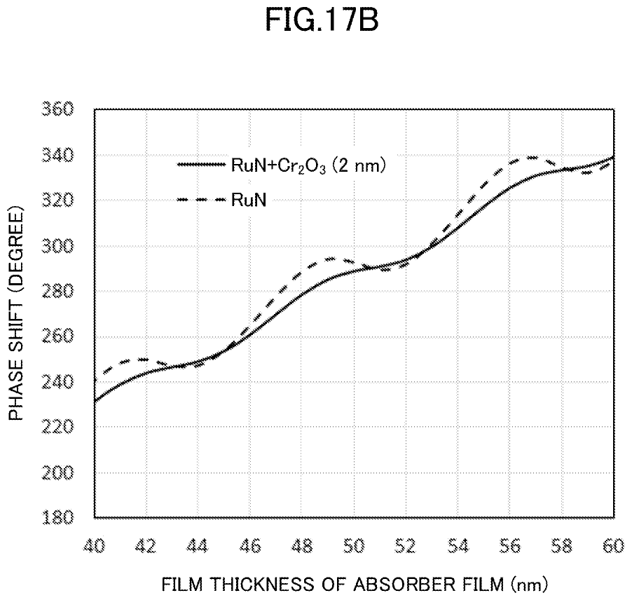

FIG. 17 shows results of simulations in which a RuN film was used as the absorber film and a Cr₂O₃ with a film thickness of 2 nm as the antireflective film was provided on the absorber film. The complex refractive index of the Cr₂O₃ film was (n′, k′)=(0.936,0.033). As can be seen in FIG. 17, by providing the antireflective film, the variation in the reflectance and the phase shift amount caused by the change in the thickness of the absorber film was reduced.

As described above, the reflective mask blank for EUVL, the reflective mask for EUVL, and the method of manufacturing the reflective mask for EUVL have been described. However, the present disclosure is not limited to the above-described embodiments, but various variations, modifications, replacements, additions, deletions, and combinations may be made without departing from the scope recited in claims. They naturally belong to the technical scope of the present disclosure.

What is claimed is:

1. A reflective mask blank for EUVL, comprising:
a substrate;
a multilayer reflective film reflecting EUV light;
an absorber film absorbing EUV light; and
an antireflective film,
the multilayer reflective film, the absorber film, and the antireflective film being formed on or above the substrate in this order,
wherein the antireflective film includes an aluminum alloy containing
aluminum (Al), and
at least one metallic element selected from the group consisting of tantalum (Ta), chromium (Cr), titanium (Ti), niobium (Nb), molybdenum (Mo), tungsten (W), and ruthenium (Ru),
the aluminum alloy further containing at least one element (X) selected from the group consisting of oxygen (O), nitrogen (N), and boron (B), and
wherein an aluminum (Al) content of component of the aluminum alloy excluding the element (X) is greater than or equal to 3 at % and less than or equal to 95 at %.

2. A reflective mask blank for EUVL comprising:
a substrate;
a multilayer reflective film reflecting EUV light;
an absorber film absorbing EUV light; and
an antireflective film,
the multilayer reflective film, the absorber film, and the antireflective film being formed on or above the substrate in this order,
wherein a refractive index n and an extinction coefficient k of the absorber film for EUV light having a wavelength of 13.5 nm and a refractive index n′ and an extinction coefficient k′ of the antireflective film for EUV light having a wavelength of 13.5 nm satisfy a relation of
$$- 0.02 < \frac{( \sqrt{{( n - {n}^{′} )}^{2} + {( k - {k}^{′} )}^{2}} - \sqrt{{( 1 - {n}^{′} )}^{2} + {k}^{{′}^{2}}} )}{2} < 0.02 .$$

3. The reflective mask blank for EUVL according to claim 2,
wherein the antireflective film includes at least one metallic element selected from the group consisting of aluminum (Al), tantalum (Ta), chromium (Cr), titanium (Ti), niobium (Nb), molybdenum (Mo), tungsten (W), and ruthenium (Ru), and further includes at least one element (Y) selected from the group consisting of oxygen (O), nitrogen (N), boron(B), hafnium (Hf), and hydrogen (H).

4. The reflective mask blank for EUVL according to claim 3,
wherein the antireflective film includes an aluminum alloy, containing aluminum (Al), at least one metallic element selected from the group consisting of tantalum (Ta), chromium (Cr), titanium (Ti), niobium (Nb), molybdenum (Mo), tungsten (W), and ruthenium (Ru), and the element (Y), and
wherein an aluminum (Al) content of component of the aluminum alloy excluding the element (Y) is greater than or equal to 3 at % and 1.0 less than or equal to 95 at %.

5. The reflective mask blank for EUVL according to claim 1,
wherein a film thickness of the antireflective film is greater than or equal to 2 nm and less than or equal to 5 nm or greater than or equal to 8 nm and less than or equal to 12 nm.

6. The reflective mask blank for EUVL according to claim 1,
wherein the absorber film includes at least one metallic element selected from the group consisting of ruthenium (Ru), chromium (Cr), tin (Sn), gold (Au), platinum (Pt), rhenium (Re), hafnium (Hf), tantalum (Ta), and titanium (Ti), and further includes at least one element (Y) selected from the group consisting of oxygen (O), nitrogen (N), boron (B), hafnium (Hf), and hydrogen (H).

7. The reflective mask blank for EUVL according to claim 1,
wherein the absorber film includes at least one metallic element selected from the group consisting of tantalum (Ta), titanium (Ti), tin (Sb), and chromium (Cr), and further includes at least one element (Y) selected from the group consisting of oxygen (O), nitrogen (N), boron (B), hafnium (Hf) and hydrogen (H).

8. The reflective mask blank for EUVL according to claim 1,
wherein the absorber film includes an alloy including tantalum (Ta) and niobium (Nb), or a compound in which at least one element (Y) selected from the group consisting of oxygen (O), nitrogen (N), boron (B), hafnium (Hf), and hydrogen (H) is added to the alloy.

9. The reflective mask blank for EUVL according to claim 1, further comprising:
a protective film for the multilayer reflective film between the multilayer reflective film and the absorber film.

10. The reflective mask blank for EUVL according to claim 1, further comprising:
a hard mask film on the antireflective film,
wherein the hard mask film includes
one element selected from the group consisting of silicon (Si) and chromium (Cr); or a compound in which at least one element selected from the group consisting of oxygen (O), nitrogen (N), carbon (C), and hydrogen (H) is added to silicon (Si) or chromium (Cr).

11. A reflective mask for EUVL, obtained by forming a pattern in the absorber film and in the antireflective film of the reflective mask blank for EUVL according to claim 1.

12. A method of manufacturing a reflective mask for EUVL, the method comprising:
forming a pattern in the absorber film and in the antireflective film of the reflective mask blank for EUVL according to claim 1.

13. The reflective mask blank for EUVL according to claim 2,
wherein a film thickness of the antireflective film is greater than or equal to 2 nm and less than or equal to 5 nm or greater than or equal to 8 nm and less than or equal to 12 nm.

14. The reflective mask blank for EUVL according to claim 2,
wherein the absorber film includes at least one metallic element selected from the group consisting of ruthenium (Ru), chromium (Cr), tin (Sn), gold (Au), platinum (Pt), rhenium (Re), hafnium (Hf), tantalum (Ta), and titanium (Ti), and further includes at least one element (Y) selected from the group consisting of oxygen (O), nitrogen (N), boron (B), hafnium (Hf), and hydrogen (H).

15. The reflective mask blank for EUVL according to claim 2,
wherein the absorber film includes at least one metallic element selected from the group consisting of tantalum (Ta), titanium (Ti), tin (Sb), and chromium (Cr), and further includes at least one element (Y) selected from the group consisting of oxygen (O), nitrogen (N), boron (B), hafnium (Hf) and hydrogen (H).

16. The reflective mask blank for EUVL according to claim 2,
wherein the absorber film includes an alloy including tantalum (Ta) and niobium (Nb), or a compound in which at least one element (Y) selected from the group consisting of oxygen (O), nitrogen (N), boron (B), hafnium (Hf), and hydrogen (H) is added to the alloy.

17. The reflective mask blank for EUVL according to claim 2, further comprising:
a protective film for the multilayer reflective film between the multilayer reflective film and the absorber film.

18. The reflective mask blank for EUVL according to claim 2, further comprising:
a hard mask film on the antireflective film,
wherein the hard mask film includes
one element selected from the group consisting of silicon (Si) and chromium (Cr); or
a compound in which at least one element selected from the group consisting of oxygen (O), nitrogen (N), carbon (C), and hydrogen (H) is added to silicon (Si) or chromium (Cr).

19. A reflective mask for EUVL, obtained by forming a pattern in the absorber film and in the antireflective film of the reflective mask blank for EUVL according to claim 2.

20. A method of manufacturing a reflective mask for EUVL, the method comprising:
forming a pattern in the absorber film and in the antireflective film of the reflective mask blank for EUVL according to claim 2.
